(19) United States
(12) Patent Application Publication
(10) Pub. No.: US 2026/0198022 A1
(43) Pub. Date: Jul. 9, 2026

(54) LOW LEAKAGE DECOUPLING CAPACITOR STRUCTURES

(71) Applicant: GlobalFoundries U.S. Inc., Malta, NY (US)

(72) Inventors: Navneet Kumar Jain, Milpitas, CA (US); Benoit Francois Claude Ramadout, DRESDEN (DE); Mohammed Ahmed Fouad Ibrahim Darwish, Dresden (DE); Kiril Biserov Borisov, Sofia (BG); Mahbub Rashed, Cupertino, CA (US)

(21) Appl. No.: 19/013,219

(22) Filed: Jan. 8, 2025

(51) Int. Cl. H10D 1/68; H10D 84/80

(52) U.S. Cl. CPC H10D 1/68; H10D 84/813

(57) ABSTRACT

The present disclosure relates to semiconductor structures and, more particularly, to low leakage decoupling capacitor structures and methods of manufacture. The structure includes: a first gate structure comprising a gate dielectric region with a first thickness; and a second gate structure adjacent to the first gate structure, the second gate structure comprising a gate dielectric region with a second thickness different from the gate dielectric region with the first thickness.

### BACKGROUND

The present disclosure relates to semiconductor structures and, more particularly, to low leakage decoupling capacitor structures and methods of manufacture.

A decoupling capacitor is a capacitor which decouples different parts of a structure. This decoupling can be done by preventing electrical energy from transferring between the different parts of the structure. For example, noise caused by circuit elements can be shunted through the capacitor, reducing its effect on the remaining portion of the circuit. Low leakage decoupling capacitors are required to reduce stand-by power and IR drop in the design.

### SUMMARY

In an aspect of the disclosure, a structure comprises: a first gate structure comprising a gate dielectric region with a first thickness; and a second gate structure adjacent to the first gate structure, the second gate structure comprising a gate dielectric region with a second thickness different from the gate dielectric region with the first thickness.

In an aspect of the disclosure, a structure comprises: a semiconductor material; at least one shallow trench isolation region isolating regions of the semiconductor material; and at least one gate structure comprising a decoupling capacitor and which spans over the semiconductor material and the at least one shallow trench isolation region, the at least one gate structure comprising a first gate dielectric region with a first thickness and a second gate dielectric region with a second thickness greater than the first thickness.

In an aspect of the disclosure, a method comprises: forming a first gate structure comprising a gate dielectric region with a first thickness; and forming a second gate structure adjacent to the first gate structure, the second gate structure comprising a gate dielectric region with a second thickness different from the gate dielectric region with the first thickness.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a top view of a layout and respective fabrication processes in accordance with aspects of the present disclosure.

FIG. 2 shows a cross-sectional view of the layout of FIG. 1 along line A-A and respective fabrication processes in accordance with aspects of the present disclosure.

FIG. 3 shows another cross-sectional view of the layout along line A-A and respective fabrication processes in accordance with aspects of the present disclosure.

FIG. 4 shows a top view of another layout and respective fabrication processes in accordance with aspects of the present disclosure.

### DETAILED DESCRIPTION

The present disclosure relates to semiconductor structures and, more particularly, to low leakage decoupling capacitor structures and methods of manufacture. More specifically, the low leakage decoupling capacitor structures may comprise a continuous gate dielectric region (e.g., oxide) with a thick gate dielectric region for an enhanced gate structure which exhibits low leakage. Also, in embodiments, the enhanced gate structures can have a transition of oxide thickness between the enhanced gate structures and standard dummy gate structures along its length, where the transition region may be provided above active regions of the device and/or under a wiring structure and/or over shallow trench isolation regions. In any configuration, there is low to no area penalty. Advantageously, the low leakage decoupling capacitor structure exhibits a very low leakage capacitor to reduce IR drop and standby current.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

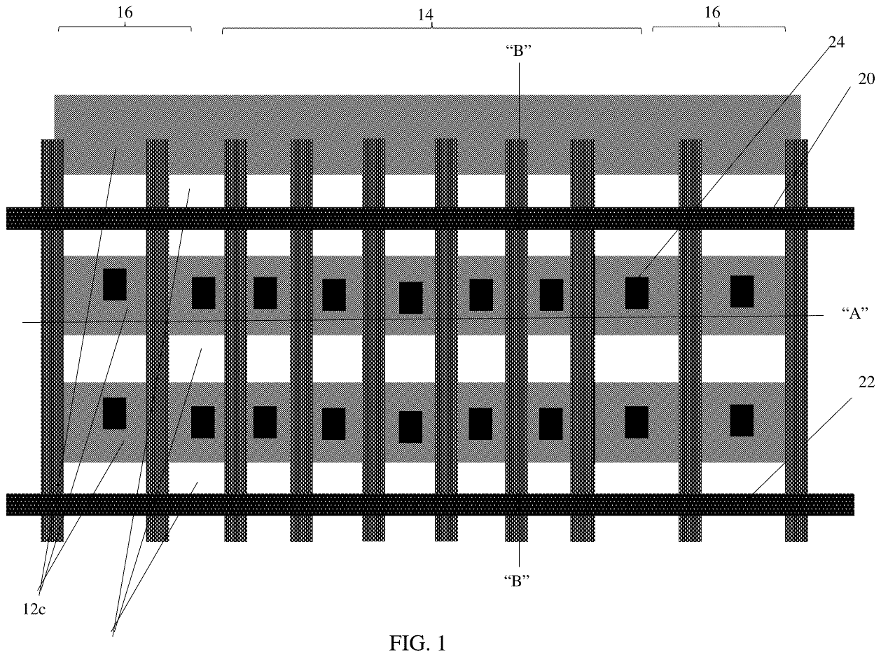

FIG. 1 shows a top view of a layout and respective fabrication processes in accordance with aspects of the present disclosure. In embodiments, the layout 10 includes a plurality of enhanced gate structures 14 and a plurality of standard gate structures 16. The plurality of enhanced gate structures 14 and a plurality of standard gate structures 16 may be NFET or PFET devices or combinations thereof. In embodiments the enhanced gate structures 14 may act as decoupling capacitors and the standard gate structures 16 may be active gate structures or dummy gate structures depending on their location and the designed performance/functionality of the device.

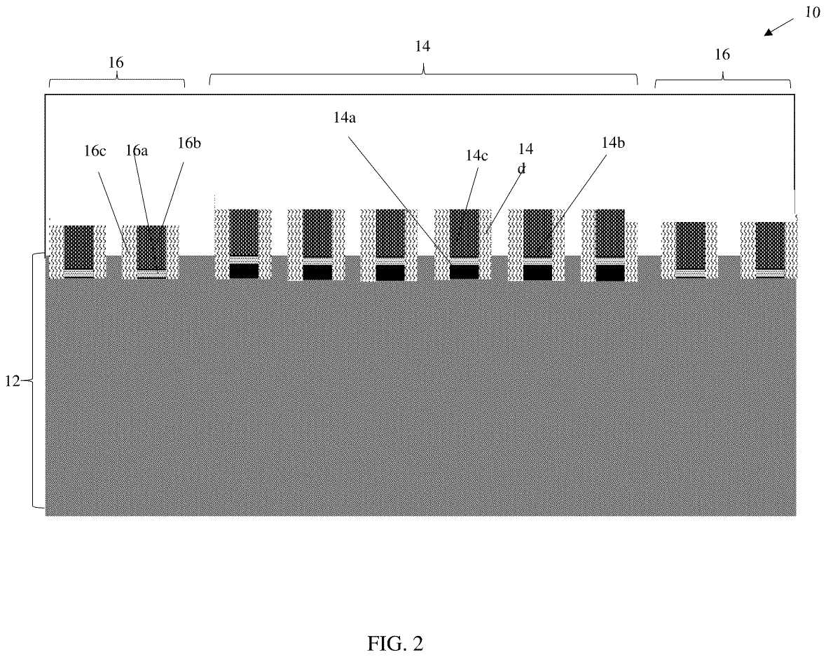

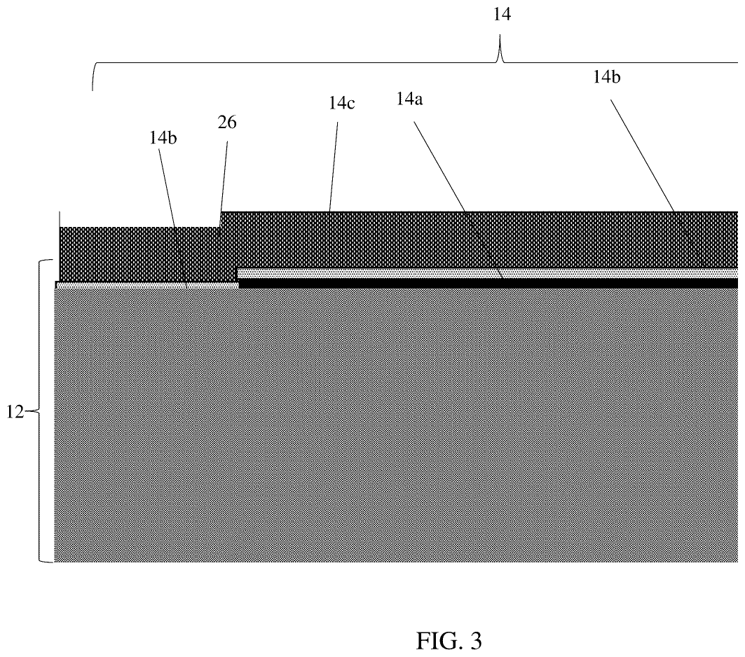

As shown in more detail in FIGS. 2 and 3, the enhanced gate structures 14 may comprise a thicker gate dielectric material and a thinner gate dielectric material, with the standard gate structures 16 comprising the thinner gate dielectric material. In embodiments, a transition between the thicker gate dielectric material and the thinner gate dielectric material can occur over a length direction, e.g., along a y-axis, of the gate structures 14 as described in more detail with respect to FIG. 3. Also, as should be understood by those of skill in the art, the thicker gate dielectric material will significantly reduce gate leakage while maintaining the same footprint as a conventional structure.

As further shown in FIG. 1, the enhanced gate structures 14 and the standard gate structures 16 span over the top semiconductor layer 12, e.g., active regions comprising a channel region and source and/or drain regions, and shallow trench isolation structures 18. In this way, the gate structures 14, 16 may comprise a channel region of the same semiconductor material, and have shared diffusion regions, e.g., source and/or drain regions. Also, in embodiments, the semiconductor material of the top semiconductor layer 12, may be, e.g., SiGe. Accordingly, the gate structures 14, 16 are fully compatible with a SiGe channel in a continuous construct without stress relaxation or similar layout effects as the top semiconductor layer 12 can straddle the boundary of the gate structure 14.

It should be recognized, though, that other semiconductor materials for the active regions are also contemplated herein. For example, the semiconductor material may be composed of any suitable material including, but not limited to, Si, SiGeC, SiC, GaAs, InAs, InP, and other III/V or II/VI compound semiconductors. Also, in embodiments, the semiconductor material 12 (which includes the active regions) may comprise any suitable single crystallographic orientation (e.g., a (100), (110), (111), or (001) crystallographic orientation). The semiconductor material 12 may be bulk semiconductor or semiconductor-on-insulator technology.

The source and drain regions may be formed by conventional ion implantation processes as is known in the art and further described herein. For example, the ion implantation processes introduce a concentration of a dopant in the semiconductor material. In embodiments, respective patterned implantation masks may be used to define selected areas exposed for the implantations. The implantation masks may include a layer of a light-sensitive material, such as an organic photoresist, applied by a spin coating process, pre-baked, exposed to light projected through a photomask, baked after exposure, and developed with a chemical developer. Each of the implantation masks has a thickness and stopping power sufficient to block masked areas against receiving a dose of the implanted ions. P-type dopants may be, e.g., Boron (B), and n-type dopants may be, e.g., Arsenic (As), Phosphorus (P) and Antimony (Sb), among other suitable examples.

FIG. 1 further shows the top semiconductor layer 12 isolated by the shallow trench isolation regions 18. The shallow trench isolation regions 18 may be formed by conventional lithography, etching and deposition methods as is known in the art and further described herein. For example, a resist formed over the semiconductor material 12 (that forms the active regions) is exposed to energy (light) and developed to form a pattern (opening). An etching process with a selective chemistry, e.g., reactive ion etching (RIE), will be used to transfer the pattern into the semiconductor material to form one or more trenches in the semiconductor material. Following the resist removal by a conventional oxygen ashing process or other known stripants, insulator material can be deposited by any conventional deposition processes, e.g., chemical vapor deposition (CVD) processes. Any residual insulator material on the surface of the semiconductor material can be removed by conventional chemical mechanical polishing (CMP) processes.

Still referring to FIG. 1, wiring structures 20, 22 may be formed over and connected to the gate structures 14, 16. In embodiments, the wiring structure 20 may be Vdd and the wiring structure 22 may be Vss (ground). The wiring structures 20, 22 may connect to the gate structures 14, 16 by conventional via interconnect structures 24, which are also shown connecting to source and drain regions of the top semiconductor layer 12. In embodiments, the gate structures 14 may include a transition between a thicker gate dielectric and a thinner gate dielectric, e.g., cell height, under the wiring structure 20, e.g., Vdd, and/or the wiring structure 22, e.g., Vss, and/or over the active regions of the top semiconductor layer 12 and/or over the shallow trench isolation structures 18, for examples. In preferred embodiments, the transition between the thicker gate dielectric material and the thinner gate dielectric material, e.g., difference in cell height, will be over the active regions.

The wiring structures 20, 22 and via interconnect structures 24 may be formed by conventional lithography, etching and deposition processes as already described herein such that no further explanation is required for a complete understanding of the present disclosure. In embodiments, the wiring structures 20, 22 may be any conventional conductive material, for example, aluminum or copper. The via interconnect structures 24 may be any conventional conductive material, for example, tungsten, etc.

Prior to forming the interconnect structures 24, a silicide process may be performed to the active regions 12 (source and drain regions) and the gate structures 14, 16. As should be understood by those of skill in the art, the silicide process begins with deposition of a thin transition metal layer, e.g., nickel, cobalt or titanium, over fully formed and patterned semiconductor devices (e.g., doped or ion implanted source and drain regions and respective devices. After deposition of the material, the structure is heated allowing the transition metal to react with exposed silicon (or other semiconductor material as described herein) in the active regions of the semiconductor device (e.g., source, drain, gate contact region) forming a low-resistance transition metal silicide. Following the reaction, any remaining transition metal is removed by chemical etching, leaving silicide contacts in the active regions 12 and the gate structures 14, 16.

FIG. 2 shows a cross-sectional view of the layout of FIG. 1 along line A-A (e.g., along the x-axis). As shown in FIG. 2, the gate structures 14, 16 have different gate dielectric thicknesses, with the gate structures 14 comprising a thicker gate dielectric layer than the gate structures 16. For example, in embodiments, the gate structures 14, e.g., enhanced gate structures 14, comprise a first gate dielectric material 14a and a second gate dielectric material 14b over the first gate dielectric material 14a; whereas the gate structures 16 only include the gate dielectric material 16a. Accordingly, in comparison, the gate structures 16 have a thinner layer of gate dielectric material.

In embodiments, the first gate dielectric material 14a may be an oxide material or other low-k dielectric material as examples. The gate dielectric material 14b may also be an oxide material or other low-k dielectric material. The gate dielectric material 16a of the gate structures 16 may also be an oxide material or other low-k dielectric material as examples. Accordingly, the gate dielectric materials 14b, 16a may be the same gate dielectric material, e.g., oxide based material. In further embodiments, the gate dielectric material 14b and the gate dielectric material 16a can include high-k dielectric materials, e.g., hafnium based materials. Accordingly, the combination of the gate dielectric material 14a and the gate dielectric material 14b of the gate structures 14 will be thicker than the gate dielectric material 16a of the gate structure 16. The gate dielectric materials 14b, 16a may be formed in the same conventional deposition processes, e.g., CVD processes, when forming the gate structures 14, 16.

The gate structures 14, 16 may also comprise a gate electrode 14c, 16b respectively. In embodiments, the gate electrodes 14c, 16b may be polysilicon material. The gate structures 14, 16 may also include sidewall spacers 14d, 16c, respectively. The sidewall spacers 14d, 16c may be any sidewall material such as oxide, nitride or combinations thereof in different materials.

Although not critical to the understanding of the present disclosure, the gate structures 14, 16 can be fabricated using conventional CMOS processes. For example, in fabricating the gate structures 14, the first gate dielectric material 14a will be formed by, for example, a conventional blanket deposition process, e.g., CVD, followed by a patterning process to remove the first gate dielectric material at certain locations for the formation of the standard gate structures 16 and, if desired, along a length of the gate structures 14. The gate dielectric material 14b, 16a and polysilicon are formed, e.g., deposited, onto the semiconductor material 12 and over the patterned gate dielectric material 14a, followed by another patterning process to form the different gate structures 14, 16. An insulator material such as nitride or oxide can be deposited on the patterned materials, followed by an anisotropic etching process to form sidewall spacers 14d, 16c.

FIG. 3 shows a cross-sectional view of the layout of FIG. 1 along line B-B (e.g., along the y-axis of the gate structure 14). In this cross-sectional view, it is shown that a gate structure 14 may comprise a thicker gate dielectric region, e.g., gate dielectric materials 14a, 14b, and a thinner gate dielectric region, e.g., gate dielectric material 14b, along its length. In this embodiment, the thicker gate dielectric region, e.g., gate oxide or dielectric materials 14a, 14b, may comprise the decoupling capacitor and the thinner gate dielectric region, e.g., gate dielectric material 14b, may comprise a dummy gate structure. Also, in embodiments, a transition region 26 between the thicker region and thinner region, e.g., regions between the decoupling capacitor and dummy gate structures, may be, for example, about 0.5 CPP (Contacted Poly Pitch) to about 1.5 CPP, although other dimensions are contemplated herein. As noted already herein, this transition region 26 can form over the active region, e.g., channel region of the semiconductor layer 12.

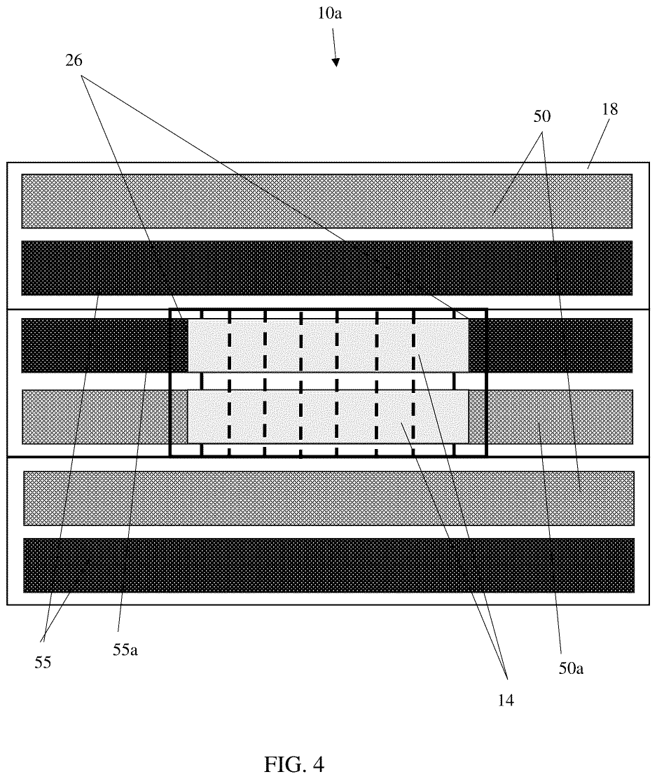

FIG. 4 shows a top view of another layout in accordance with aspects of the present disclosure. In the layout 10a of FIG. 4, a plurality of gate structures 50, 50a, 55, 55a are separated by shallow trench isolation regions 18. In embodiments, the gate structures 50, 50a may be NFET devices; whereas the gate structures 55, 55a may be PFET devices. In embodiments, the gate structures 50, 55 may be active devices similar to the gate structures 16, e.g., with a thinner gate dielectric material. In further embodiments, the gate structures 50a, 50b include regions comprising the thinner gate dielectric material and the thicker dielectric material, e.g., enhance gate structure as representatively shown at reference numeral 14. The gate structures 50a, 50b also include dummy gate regions with only the thinner gate dielectric region, with a transition region 26 between the thicker gate dielectric region and the thinner gate dielectric region.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a first gate structure comprising a gate dielectric region with a first thickness; and
a second gate structure adjacent to the first gate structure, the second gate structure comprising a gate dielectric region with a second thickness different from the gate dielectric region with the first thickness.

2. The structure of claim 1, wherein the first gate structure comprises a decoupling capacitor and the second gate structure comprises an active gate structure or a dummy gate structure.

3. The structure of claim 2, wherein the gate dielectric region with the first thickness is greater than the gate dielectric region with the second thickness.

4. The structure of claim 2, wherein the gate dielectric region of the first gate structure comprises the first thickness and the second thickness, and the gate dielectric region of the first thickness is a different height than the gate dielectric region with the second thickness along a length of the first gate structure.

5. The structure of claim 4, wherein the gate dielectric region comprising the first thickness includes multiple gate dielectric materials.

6. The structure of claim 5, wherein the multiple gate dielectric materials comprise a bottom oxide material that sits on a semiconductor substrate.

7. The structure of claim 6, wherein the bottom oxide material is devoid from the gate dielectric region of the second thickness.

8. The structure of claim 5, wherein the gate dielectric region with the second thickness has a same gate dielectric material as an upper gate dielectric material of the gate dielectric region with the first thickness.

9. The structure of claim 8, wherein the upper gate dielectric material of the gate dielectric region has a same thickness as the second thickness.

10. The structure of claim 3, further comprising a transition region between the gate dielectric region with the first height and the gate dielectric region with the second height.

11. The structure of claim 10, wherein the transition region is provided over semiconductor material.

12. The structure of claim 1, wherein the gate dielectric region of the first thickness is greater than the gate dielectric region of the second thickness.

13. The structure of claim 12, wherein the gate dielectric region of the first thickness comprises two dielectric materials and the gate dielectric region second thickness comprises a same dielectric material as one of the two dielectric materials.

14. A structure comprising:
a semiconductor material;
at least one shallow trench isolation region isolating regions of the semiconductor material; and
at least one gate structure comprising a decoupling capacitor and which spans over the semiconductor material and the at least one shallow trench isolation region, the at least one gate structure comprising a first gate dielectric region with a first thickness and a second gate dielectric region with a second thickness greater than the first thickness.

15. The structure of claim 14, wherein the first thickness and the second thickness are along a length of the at least one gate structure.

16. The structure of claim 14, wherein the first gate dielectric region comprises multiple gate dielectric layers.

17. The structure of claim 15, wherein a top gate dielectric layer of the multiple gate dielectric layers is a same material as dielectric materials of the second gate dielectric region.

18. The structure of claim 15, further comprising at least a second gate structure comprising an active gate structure with dielectric material having a thickness less than a combined thickness of the first gate dielectric region and the second gate dielectric region.

19. The structure of claim 14, further comprising a transition between the first gate dielectric region and the second gate dielectric region, the transition being located over an active region of the active semiconductor substrate.

20. A method comprises:
forming a first gate structure comprising a gate dielectric region with a first thickness; and
forming a second gate structure adjacent to the first gate structure, the second gate structure comprising a gate dielectric region with a second thickness different from the gate dielectric region with the first thickness.
